(19) United States
(12) Patent Application Publication
(10) Pub. No.: US 2026/0139782 A1
(43) Pub. Date: May 21, 2026

(54) SELF-CENTERING FLOATING FLUID COUPLER

(71) Applicant: AMD Design, LLC, Wilmington, DE (US)

(72) Inventors: Jacqueline KIM, Fort Lee, NJ (US); Yuan ZHANG, Hackensack, NJ (US); Chen AN, Bergenfield, NJ (US)

(73) Assignee: AMD Design, LLC, Wilmington, DE (US)

(21) Appl. No.: 18/955,200

(22) Filed: Nov. 21, 2024

(51) Int. Cl. F16L 37/53; H05K 7/20

(52) U.S. Cl. CPC F16L 37/53; H05K 7/20272; H05K 7/20781

(57) ABSTRACT

The self-centering floating fluid coupler includes a body having a first port and one or more second ports in communication with the first port. The fluid coupler also includes a housing assembly surrounding the body. The housing assembly includes a first opening exposing the first port of the body and a second opening exposing the one or more second ports of the body. The fluid coupler further includes one or more bias members disposed within the housing and configured to bias the body to a central position within the housing assembly. The body is able to move within the housing assembly to accommodate misalignments between the first port and a corresponding connection location (e.g., a mating fitting). Furthermore, the body is biased back to the central position when connections are removed. Accordingly, the fluid coupler allows for a broad range of misalignments.

### FIELD

This disclosure is directed to floating fluid couplers, such as floating fluid couplers used in blind liquid-cooling connections in computing environments.

### BACKGROUND

Fluid couplers are often used to connect fluid lines together. For example, fluid couplers are often used to connect fluid lines of liquid-cooled servers to cooling systems (e.g., rack cooling systems, manifolds, facility cooling lines, heat exchangers, etc.). In many cases, the fluid couplers have integrated, or have attached to them, blind quick-disconnect (QD) fittings to enable the fluid lines of the servers to connect to the cooling systems. The blind QD fittings enable the necessary connections to be made “blind,” or without seeing the connections. For example, many times, servers are simply inserted into server racks such that the blind QD fittings on the fluid couplers interface/connect with blind QD fittings on the cooling systems.

Often times, mating blind QD fittings (e.g., one attached to a server, and one attached to a cooling system) are not exactly aligned. For example, due to tolerances in the racks and/or the servers, axes of the mating blind QD fittings can be misaligned by many millimeters and/or degrees. The misalignment can lead to large insertion forces (e.g., due to forcing the alignment), result in poor fluid connections (e.g., leaking or failure), result in breaking of components, and/or require large removal forces.

### SUMMARY

A self-centering fluid coupler and associated assemblies are described herein. The self-centering fluid coupler includes a body having a first port and one or more second ports in communication with the first port. The fluid coupler also includes a housing assembly surrounding the body. The housing assembly includes a first opening exposing the first port of the body and a second opening exposing the one or more second ports of the body. The fluid coupler further includes one or more bias members disposed within the housing and configured to bias the body to a central position within the housing assembly.

A fluid coupler assembly is described herein. The fluid coupler assembly includes the self-centering fluid coupler described above, a blind QD fitting attached to the first port, and fluid fittings attached to each of the second ports.

A server assembly is described herein. The server assembly includes a chassis and the fluid coupler assembly described above.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example fluid coupler assembly.

FIG. 2 illustrates an exploded view of the example fluid coupler assembly.

FIG. 3A illustrates an example misalignment of the example fluid coupler assembly with a first blind QD fitting while the example fluid coupler assembly is in a central position.

FIG. 3B illustrates the example fluid coupler assembly with a body of the example fluid coupler assembly displaced relative to a housing assembly of the example fluid coupler assembly such that axes of a blind QD fitting of the example fluid coupler assembly and the first blind QD fitting are aligned.

FIG. 4A illustrates an example misalignment of the example fluid coupler assembly with a second blind QD fitting while the example fluid coupler assembly is in the central position.

FIG. 4B illustrates the example fluid coupler assembly with the body displaced relative to the housing assembly such that axes of the blind QD fitting of the example fluid coupler assembly and the second blind QD fitting are aligned.

FIG. 5 illustrates an example system of a server rack and a server with a plurality of the fluid coupler assemblies installed therein.

### DETAILED DESCRIPTION

### Overview

Mating blind QD fittings (e.g., those between server and rack cooling systems) can be difficult due to misalignments between the blind QD fittings. For example, due to tolerances in the racks and/or the servers, axes of the mating blind QD fittings can be misaligned by many millimeters and/or degrees. The misalignment can lead to large insertion forces (e.g., due to forcing the alignment), result in poor fluid connections (e.g., leaking or failure), result in breaking of components, and/or require large removal forces.

While some blind QD fittings allow for some misalignment between mating fittings, they are often limited in their ability to mitigate larger misalignments, especially displacements (e.g., offsets of connecting fittings in a plane normal to a mating direction). Furthermore, conventional QD fittings may be unable to effectively return to a central position (e.g., a center point between maximum misalignments) when they are displaced (e.g., one part moved relative to another to accommodate the misalignment). As such, unless they are “reset” to a central position, they may have to adapt to much larger misalignments on future connections (e.g., because of having to first “go past” the central position), which may not be possible given their limited adaptability.

A self-centering floating fluid coupler is described herein. The self-centering floating fluid coupler includes a body having a first port and one or more second ports in communication with the first port. The fluid coupler also includes a housing assembly surrounding the body. The housing assembly includes a first opening exposing the first port of the body and a second opening exposing the one or more second ports of the body. The fluid coupler further includes one or more bias members disposed within the housing and configured to bias the body to a central position within the housing assembly. The body is able to move within the housing assembly to accommodate misalignments between the first port and a corresponding target location (e.g., a mating fitting).

The self-centering floating fluid coupler is adaptable for many fluid fittings (e.g., blind QD fittings, QD fittings, plumbing connections, etc.) while allowing for a large amount of misalignment between the self-centering floating fluid coupler and a target fitting. Furthermore, because the self-centering floating fluid coupler is biased towards the central position, it may be well adapted for changing connection environments (e.g., different target connections).

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Fluid Coupler Assembly

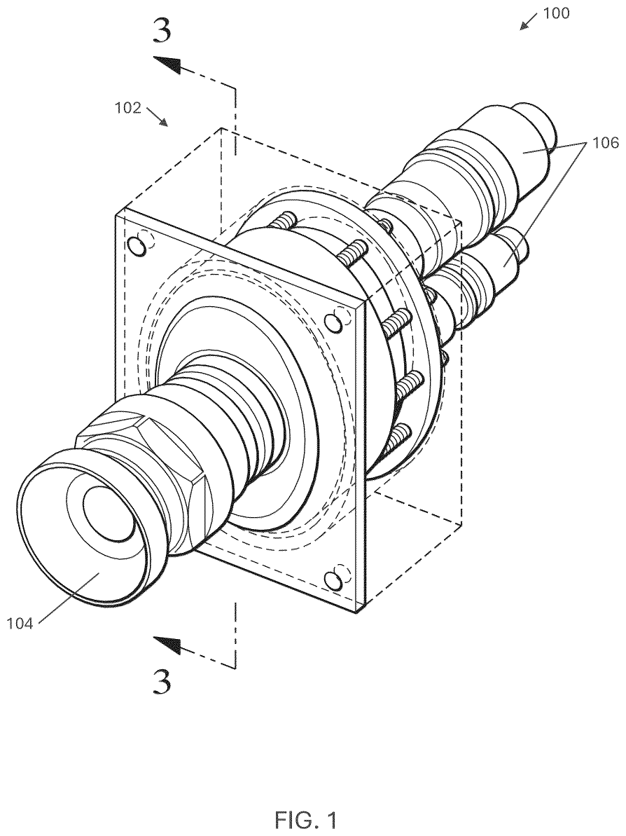

FIG. 1 illustrates an example of a fluid coupler assembly 100. The fluid coupler assembly 100 includes a self-centering floating fluid coupler 102, at least one first QD fitting 104, and one or more second fittings 106. The fluid coupler assembly 100 may be configured to be mounted to a server to interface with a cooling system (e.g., on a rack) or to the cooling system to interface with a server. In many cases, the fluid coupler assembly 100 may be configured to mount to a server, as the cooling system often has manifolds which may be harder to integrate the fluid coupler assembly 100 with. Regardless, the fluid coupler assembly 100 may be universal in mounting location.

The first QD fitting 104 may be a blind (or blind-mate) QD fitting (male or female) configured to mate with a corresponding fitting (e.g., on a cooling system or on a server). As illustrated, the first QD fitting 104 is a female QD fitting. Accordingly, the first QD fitting 104 may be configured to interface with a male QD fitting (e.g., blind QD fitting) on a cooling system (e.g., rack).

The first QD fitting 104 may be inserted, threaded, press-fit, adhered, or otherwise coupled with a first port of the self-centering floating fluid coupler 102. If there are multiple first QD fittings 104, then they may be coupled with respective first ports of the self-centering floating fluid coupler 102.

The second fittings 106 may be QD fittings or any other plumbing connections attached to the self-centering floating fluid coupler 102. For example, the second fittings 106 may be manual (or manual-mate) QD fittings (as illustrated), barbed adapters, push-to-connect adapters, and/or compression fittings. The second fittings 106 may be inserted, threaded, press-fit, adhered, or otherwise coupled with respective second ports of the self-centering floating fluid coupler 102. The second fittings 106 may be configured to be coupled with fluid lines of a liquid-cooled server (when the fluid coupler assembly 100 is configured to be mounted on the liquid-cooled server) or with fluid lines/a manifold (when the fluid coupler assembly 100 is configured to be mounted on a cooling system).

In some implementations, one or more of the fittings may be integral with the self-centering floating fluid coupler 102. For example, one or more of the fittings may be formed/be a part of a body of the self-centering floating fluid coupler 102. Otherwise, they may be configured to couple with the self-centering floating fluid coupler 102 (specifically, a body thereof).

Any number of plumbing combinations may be used between the first QD fitting 104 and the second fittings 106. For example, the first QD fitting 104 may be a single fitting, the second fittings 106 may be two fittings, and the first QD fitting 104 may be in communication with both of the second fittings 106 (e.g., a 2-to-1 coupler). Alternatively, the first QD fitting 104 may be two fittings, the second fittings 106 may be two fittings, and each of the first QD fittings 104 may be in combination with one of the second fittings 106 (e.g., a 2 -to-2 coupler). There may also be more than two fittings on a side. Thus, any number of first QD fittings 104 may be used with any number of second fittings 106 with any number of fluid communication paths therebetween. Furthermore, the fittings may be any types or sizes and may vary between the sides of the fluid coupler assembly 100 (e.g., left/right, inlet/outlet, first QD fitting 104/second fittings 106) and/or between fittings on a single side of the fluid coupler assembly 100.

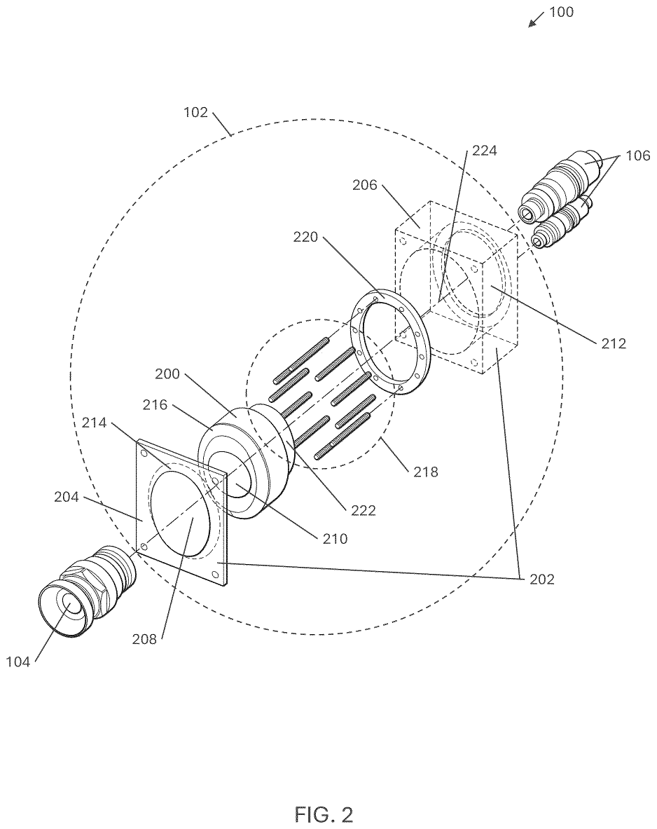

FIG. 2 illustrates an exploded view of the fluid coupler assembly 100 with the self-centering floating fluid coupler 102. As described above, the fluid coupler assembly 100 includes the self-centering floating fluid coupler 102, the first QD fitting 104, and the second fittings 106.

The self-centering floating fluid coupler 102 includes a housing assembly 202 and a body 200 configured to be disposed within the housing assembly 202. The housing assembly 202 is configured to allow the body 200 to move relative to the housing assembly 202 to mitigate misalignment at the first QD fitting 104. The housing assembly 202 may include a first housing portion 204 and a second housing portion 206 that are configured to be coupled together around the body 200. The first housing portion 204 is illustrated as a plate while the second housing portion 206 is illustrated as a structure with a cavity. It should be noted that the separation plane may be anywhere within the housing assembly 202 (e.g., both the first housing portion 204 and the second housing portion 206 may have respective cavities configured to accommodate portions of the body 200). The first housing portion 204 and the second housing portion 206 may be screwed, bolted, adhered, snap-fit or otherwise coupled to contain the body 200 within the housing assembly 202.

The housing assembly 202 may include a mounting portion configured to attach the self-centering floating fluid coupler 102 (and the fluid coupler assembly 100) to a server chassis or to a cooling system. By mounting the housing assembly 202 to the server, a relative motion between the body 200 and the housing assembly 202 may be realized.

The first housing portion 204 may include a first opening 208 configured to expose at least one first port 210 within the body 200. The first port 210 may be a single port configured to interface with the first QD fitting 104. Similarly, the second housing portion 206 may include a second opening 212 configured to expose one or more second ports within the body 200. The second ports may be two ports configured to interface with the second fittings 106 and may be the same or different sizes than the first port 210. Furthermore, when there are multiple second ports, the second ports may be different sizes. The second ports may be on an opposite side of the body as the first port 210 and may be communicatively coupled with the first port 210 in any number of combinations (e.g., those discussed above in regard to the fittings). To interface with fittings, the first port 210 and/or the second ports may be threaded holes.

On an edge of the first opening 208 may be a housing chamfer 214. The housing chamfer 214 may be configured to face an interior of the housing assembly 202 (e.g., toward the body 200). The body 200 may include a body chamfer 216 on an edge of the body 200 that surrounds the first port 210. The body chamfer 216 may be configured to interface with the housing chamfer 214 to center the body 200 relative to the housing assembly 202 when one or more bias members 218 act thereon.

The bias members 218 may include springs, elastomers, or any other members configured to bias the body 200 towards the housing chamfer 214 (e.g., left in the illustrated example). In the illustrated example, there are ten bias members 218 arranged in an array around the second ports; however, there may be any number of bias members 218. The array may be circular, oval, square, or any other shape. The bias members 218 may be configured to bias the body 200 with a force that is greater than an insertion force of a corresponding fitting (e.g., the first QD fitting 104).

There may be a bias member locator 220 (e.g., a washer with respective holes for the bias members 218) disposed within the housing assembly 202 that is configured to locate the bias members 218 (e.g., maintain relative locations of at least ends of the bias members 218). The bias member locator 220 may also be formed within the second housing portion 206 (e.g., holes or other features drilled/formed within the second housing portion 206). Similarly, the bias members 218 may be disposed within respective holes in the body 200 to maintain relative locations of at least other ends of the bias members 218.

In some implementations, the bias members 218 may include a wave spring disposed surrounding the second ports. Furthermore, the bias members 218 may not surround the second ports in some implementations. For example, a single bias member 218 may be disposed between the second ports configured to bias the body 200 toward the housing chamfer 214.

The bias members 218, by biasing the body 200 towards the housing chamfer 214, may cause the body chamfer 216 to interface with the housing chamfer 214 to bias the body 200 towards a central position where the body chamfer 216 is centered on the housing chamfer 214. When the body 200 is forced to move relative to the housing assembly 202 (e.g., due to misalignment at the first port 210), the bias members 218 may deform/stretch/compress to allow for the body 200 to move relative to the housing assembly 202 (e.g., the body chamfer 216 may slide relative to the housing chamfer 214). When the fluid coupler assembly 100 is removed from the fitting that is misaligned from the first port 210, the bias members 218 may cause the body 200 to return to the central position.

The body 200 may have a shoulder portion 222 with a smaller cross section than a largest cross section of the body 200. The shoulder portion 222 may be configured to support the bias members 218. Holes may be formed in the body 200 surrounding the shoulder portion 222 to accommodate the bias members 218.

The body 200 may have a central axis 224 that is parallel to an axis of the first port and that passes through a centroid of the body 200. In the illustrated example, the first port 210 is concentric with the central axis 224, but that may vary depending upon implementation.

The body 200 may also be oblong, especially if one or more of the sides has multiple ports (e.g., two second ports). In other words, the body 200 may not be cylindrical in shape. As illustrated, the body 200 takes an oblate cylinder shape. In other words, each cross section along the central axis 224 may be an oval, with multiple cross sections having the same outer size. Doing so may enable a smaller footprint than having the body 200 be round in cross section.

It should be noted that the oblong shape of the body 200 may cause the first opening 208 and the second opening 212 (and, thus, the body chamfer 216 and the housing chamfer 214) to be oval shape. Doing so may not only keep the size to a minimum but may also keep the body 200 from rotating around the central axis 224. In some implementations, however, portions of the body 200 may be cylindrical. For example, the housing chamfer 214 may be round and disposed on a cylindrical portion of the body 200. Accordingly, in such implementations, the housing chamfer 214 may also be circular. Although the body 200 is shown/described as a single structure, in some implementations, it may be formed by a plurality of components. In such implementations, components of the body 200 may be adhered, fastened, clipped, or otherwise attached together to form the body 200.

It should also be noted that the sides of the fluid coupler assembly 100 may be switched without departing from the scope of this disclosure. For example, while it may be beneficial to have the bias members 218 bias the body 200 towards a blind QD fitting (or a side configured to receive a blind QD fitting), the bias members 218 may also bias the body 200 towards the second fittings 106. In other words, the second fittings 106 and the first QD fitting 104 may switch sides. In such implementations, the body chamfer 216 may be opposite the first QD fitting 104 instead of proximate it. Again, it may be beneficial, though, to have the body chamfer 216 and the housing chamfer 214 proximate the fitting causing the misalignment (e.g., as in the illustrated example).

The structures of the present disclosure may be formed of any suitable materials. For example, the QD fittings 104 and/or the second fittings 106 may be formed of brass, copper, steel, stainless steel, aluminum, glass, some alloy or combination thereof, or any other material or composition of materials. In at least some cases, the QD fittings 104 may be formed of a stainless steel. The material(s) of the fittings may be selected for structural strength (e.g., to withstand repeated couplings/de-couplings, forceful couplings/de-couplings, frequent couplings/de-couplings, rare couplings/de-couplings, to withstand hose tension, or for other reasons).

The housing assembly 202, the body 200, and/or portions thereof may, for example, be formed of rubber, plastic, glass, metal (e.g., aluminum alloy or stainless steel), a composite material, or some other suitable material. For example, a material of the housing assembly 202 (e.g., the first housing portion 204) may be selected having parameters that conform to a desired strength, durability, surface smoothness, hardness, or the like. In some cases, the material of body 200 may be selected having parameters that conform to a desired pliability, durability, mechanical stability, temperature stability, or the like. The material may in some cases be colored to substantially indicate the material of the body 200 or its associated properties. The body 200 may be a solid material, a hollow material (e.g., a material having one or more open or sealed voids, said void area filled with a liquid, a gas, or the ambient atmosphere around the coupler assembly) or a combination of solid and hollow materials. In some cases, the body 200 may be compressed when integrated with the housing assembly 202 to assist the bias members 218, envelop some or all of the bias members 218, or act as one or more bias members 218.

### Example Misalignments

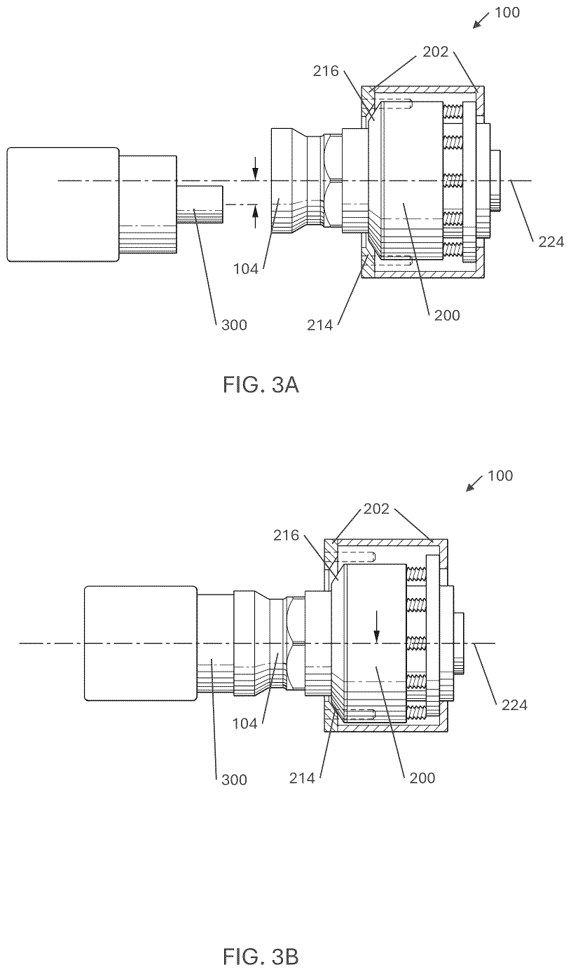

FIGS. 3A and 3B illustrate an example misalignment of the fluid coupler assembly 100 with a first blind QD fitting 300. A portion of the housing assembly 202 is illustrated as cut away (e.g., section line 3 in FIG. 1) to show the body 200. The first blind QD fitting 300 may be a fitting on a rack manifold, for example, and is offset down relative to the central position of the fluid coupler assembly 100. FIG. 3A illustrates the fluid coupler assembly 100 in the central position prior to engagement with the first blind QD fitting 300. FIG. 3B illustrates the fluid coupler assembly 100 after engagement with the first blind QD fitting 300, where the body 200 has shifted relative to the housing assembly 202 to accommodate the misalignment.

It should be noted that a maximum amount of misalignment may be dictated by the female fitting of the QD fittings (e.g., the first QD fitting 104). For example, if the first blind QD fitting 300 is misaligned greater than a radius of an insertion section of the first QD fitting 104, the first blind QD fitting 300 may move past the first QD fitting 104 without interfacing with it, thereby not causing the body 200 to shift which doesn't cause the QD fittings to mate. If the male/female fittings are switched, the same applies.

As stated above, the fluid coupler assembly 100 is in the central position when un-coupled with a target connection (e.g., the first blind QD fitting 300). That is, the body chamfer 216 may be centered on the housing chamfer 214.

When the first blind QD fitting 300 interfaces with the first QD fitting 104 (e.g., upon insertion or as the fluid coupler assembly 100 is moved from right to left in the illustrated example), a lead in chamfer on the first QD fitting 104 causes the first QD fitting 104 to be forced down in the illustrated example. Because the first QD fitting 104 is coupled with the body 200, the body 200 is also forced down. The housing assembly 202 is generally fixed to a server and, thus, can only move left to right in the illustrated example. As such, the body 200 is forced to move relative to the housing assembly 202, as illustrated in FIG. 3B. The relative move can be seen by a space on top of the first QD fitting 104 being larger than a space below the first QD fitting 104 in FIG. 3B. Furthermore, the central axis 224 can be seen to shift down relative to the housing assembly 202 between FIGS. 3A and 3B.

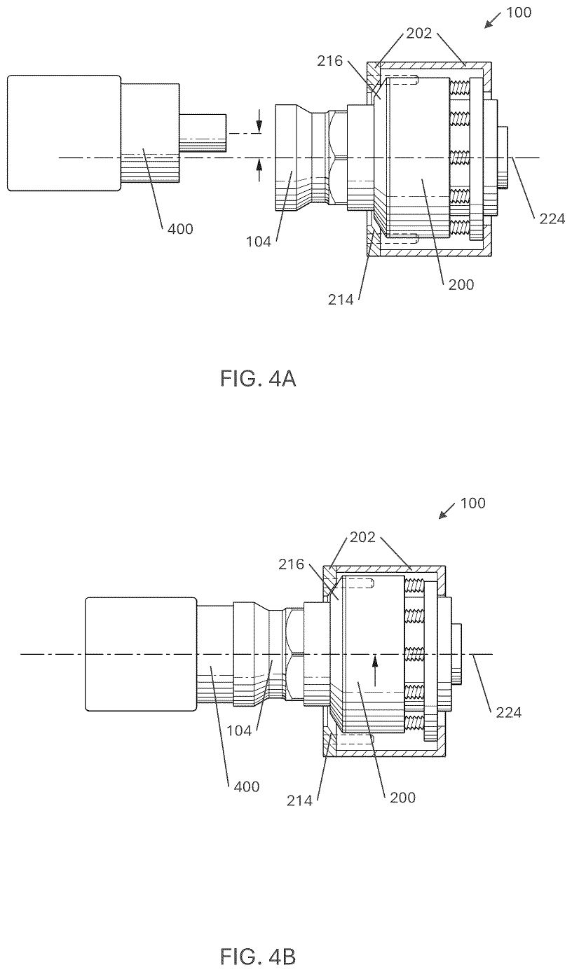

FIGS. 4A and 4B illustrate an example misalignment of the fluid coupler assembly 100 with a second blind QD fitting 400. A portion of the housing assembly 202 is illustrated as cut away (e.g., section line 3 in FIG. 1) to show the body 200. The second blind QD fitting 400 may be another fitting on the rack manifold or a fitting on another rack manifold, for example, and is offset up relative to the central position of the fluid coupler assembly 100. FIG. 4A illustrates the fluid coupler assembly 100 in the central position prior to engagement with the second blind QD fitting 400. FIG. 4B illustrates the fluid coupler assembly 100 after engagement with the second blind QD fitting 400, where the body 200 has shifted relative to the housing assembly 202 to accommodate the misalignment.

The central position may be achieved responsive to disconnecting the fluid coupler assembly 100 from the first blind QD fitting 300. Because the fluid coupler assembly 100 is self-centering (e.g., due to the bias members 218 and the chamfers), the fluid coupler assembly returns to the central position regardless of position from a previous connection. That is, there is no memory associated with the previous connection. The connection with the second blind QD fitting 400 may also be the first connection of the fluid coupler assembly 100 (e.g., without first connecting to another QD fitting).

It should be noted that a maximum amount of misalignment may be dictated by the female fitting of the QD fittings (e.g., the first QD fitting 104). For example, if the second blind QD fitting 400 is misaligned greater than a radius of an insertion section of the first QD fitting 104, the second blind QD fitting 400 may move past the first QD fitting 104 without interfacing therewith. Doing so would not cause the body 200 to shift to enable the QD fittings to mate. In other words, the connection would not be made. If the male/female fittings are switched, the same applies.

As stated above, the fluid coupler assembly 100 is in the central position when un-coupled with a target connection (e.g., the second blind QD fitting 400). That is, the body chamfer 216 may be centered on the housing chamfer 214.

When the second blind QD fitting 400 interfaces with the first QD fitting 104 (e.g., upon insertion or as the fluid coupler assembly 100 is moved from right to left in the illustrated example), a lead in chamfer on the first QD fitting 104 causes the first QD fitting 104 to be forced up in the illustrated example. Because the first QD fitting 104 is coupled with the body 200, the body 200 is also forced up. The housing assembly 202 is generally fixed to a server and, thus, can only move left to right in the illustrated example. As such, the body 200 is forced to move relative to the housing assembly 202, as illustrated in FIG. 4B. The relative move can be seen by a space on top of the first QD fitting 104 being smaller than a space below the first QD fitting 104 in FIG. 4B. Furthermore, the central axis 224 can be seen to shift up relative to the housing assembly 202 between FIGS. 4A and 4B.

### Example System

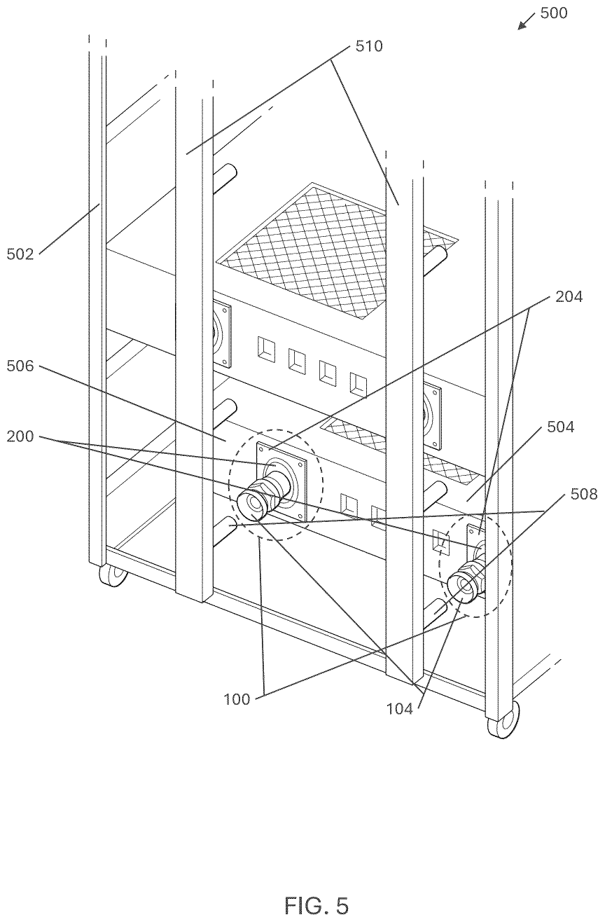

FIG. 5 illustrates an example system 500 of a server rack 502 and a server 504 with a plurality of the fluid coupler assemblies 100 installed therein. The fluid coupler assemblies 100 may correspond to influent and effluent flows of the server 504. Although the fluid coupler assemblies 100 are shown with a wall 506 of the server 504 between the first housing portions 204 and the second housing portions 206 (occluded by the wall 506), the fluid coupler assemblies 100 may be disposed anywhere relative to the wall 506 (e.g., further within the server 504 or further outside of the server 504). The server rack 502 includes a plurality of rack QD fittings 508 that are configured to interface with the QD fittings 104 of the fluid coupler assemblies 100. As shown, groups of the rack QD fittings 508 may be connected to respective manifolds 510 (e.g., influent and effluent).

To connect the QD fittings 104 to the rack QD fittings 508, the server 504 may be inserted into the server rack 502. The server rack 502 may have guiding portions configured to at least partially align the respective fittings. As discussed above, however, due to tolerances, the fittings may not be exactly aligned. Once the QD fittings 104 begin to interface with the rack QD fittings 508, the server 504 may be further inserted into the server rack 502. Doing so, assuming there is misalignment and it is within a range of the lead in features of the QD fittings 104, causes the QD fittings 104 to deflect, as discussed above, which causes the body 200 to move relative to the housing assembly 202. The QD fittings 104 and the rack QD fittings 508 may be mated at a certain insertion location of the server 504.

When the server 504 is removed from the server rack 502 (or when the server 504 is pulled far enough out that the QD fittings 104 separate from the rack QD fittings 508), the bodies 200 may return to a neutral position relative to the housing assembly 202 (e.g., they self-center). Doing so ensures that the fluid coupler assemblies 100 are able to engage with a wide variety of QD fittings 104 (e.g., ones other than those they just disconnected from).

By allowing for misalignment and being self-centering, the self-centering floating fluid coupler 102 (and, by inclusion, the fluid coupler assembly 100 and/or a server) can enable fluid connections to be made with a large variety of target connections. For example, the self-centering floating fluid coupler 102 may enable misalignments up to and above 3.5 millimeters orthogonally to the central axis 224. Furthermore, having multiple second ports (e.g., for connecting the second fittings 106 thereto) can enable the self-centering floating fluid coupler 102 to become a floating manifold with multiple inputs or outputs. Accordingly, the overall space requirement for fluid connections may be minimized.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

The server may also include a power supply configured to supply power to various components within the server. The power supply may be configured to adapt or change incoming power (e.g., alternating current to direct current and/or stepping up or stepping down voltage). Furthermore, the power supply may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionality of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### EXAMPLES

### Example 1

A self-centering floating fluid coupler comprising: a body including: a first port; and one or more second ports in communication with the first port; a housing assembly surrounding the body, wherein the housing assembly includes: a first opening exposing the first port of the body; and a second opening exposing the one or more second ports of the body; and one or more bias members disposed within the housing and configured to bias the body to a central position within the housing assembly.

### Example 2

The self-centering floating fluid coupler of example 1, wherein the one or more bias members are configured to bias the body towards the first opening of the housing assembly or the second opening of the housing assembly.

### Example 3

The self-centering floating fluid coupler of example 1 or 2, wherein: the housing assembly includes a housing chamfer on an edge of the first opening or an edge of the second opening; and the body includes a body chamfer on an edge surrounding the first port or an edge surrounding the one or more second ports.

### Example 4

The self-centering floating fluid coupler of example 3, wherein: the housing chamfer of the housing and the body chamfer of the body are configured to interface with one another; and the central position corresponds to a position where the body chamfer of the body is centered on the housing chamfer of the housing.

### Example 5

The self-centering floating fluid coupler of any previous example, wherein the one or more bias members comprise a plurality of bias members disposed in an array.

### Example 6

The self-centering floating fluid coupler of example 5, wherein the one or more bias members are disposed within respective holes in the body.

### Example 7

The self-centering floating fluid coupler of example 5 or 6, wherein the self-centering floating fluid coupler includes a bias member locator configured to locate the one or more bias members relative to the housing assembly.

### Example 8

The self-centering floating fluid coupler of any previous example, wherein the housing assembly includes a first portion and a second portion configured to be coupled with one another to surround the body.

### Example 9

The self-centering floating fluid coupler of any previous example, wherein at least one of the first port of the body or the one or more second ports of the body are threaded holes.

### Example 10

The self-centering floating fluid coupler of any previous example, wherein: the one or more second ports of the body are two ports; and the two ports are in communication with the first port of the body.

### Example 11

The self-centering floating fluid coupler of example 10, wherein the two ports of the one or more second ports of the body are different sizes.

### Example 12

The self-centering floating fluid coupler of example 10 or 11, wherein the body has an oblong shape about an axis parallel to the first port of the body and the one or more second ports of the body that passes through a centroid of the body.

### Example 13

The self-centering floating fluid coupler of example 10, 11, or 12, wherein at least one of the first opening of the housing assembly or the second opening of the housing assembly has an oval shape.

### Example 14

The self-centering floating fluid coupler of any previous examples, wherein the housing assembly is configured to allow the body to move at least 3 millimeters orthogonally to an axis of the first opening of the housing assembly and an axis of the second opening of the housing assembly.

### Example 15

The self-centering floating fluid coupler of any previous examples, wherein the housing assembly includes a mounting portion configured to mount the self-centering floating fluid coupler to an external structure.

### Example 16

A fluid coupler assembly comprising: a self-centering floating fluid coupler including: a body including: a first port; and one or more second ports in communication with the first port; a housing assembly surrounding the body, wherein the housing assembly includes: a first opening exposing the first port of the body; and a second opening exposing the one or more second ports of the body; and one or more bias members disposed within the housing and configured to bias the body to a central position within the housing assembly; a blind quick-disconnect (QD) fitting attached to the first port of the body; and fluid fittings attached to each of the one or more second ports of the body.

### Example 17

The fluid coupler assembly of example 16, wherein: the one or more second ports of the body are two ports; and the two ports are in communication with the first port of the body.

### Example 18

The fluid coupler assembly of example 16 or 17, wherein: the one or more bias members include a plurality of bias members disposed in an array; and the plurality of bias members are configured to bias the body towards the first opening of the housing assembly or the second opening of the housing assembly.

### Example 19

The fluid coupler assembly of example 18, wherein: the body includes an edge surrounding the first port of the body or the one or more second ports of the body; and the central position corresponds to a position where the edge of the body is centered on the first opening of the housing assembly or the second opening of the housing assembly.

### Example 20

A server assembly comprising: a chassis; and a fluid coupler assembly including: a self-centering floating fluid coupler including: a body including: a first port; and one or more second ports in communication with the first port; a housing assembly surrounding the body and attached to the chassis, wherein the housing assembly includes: a first opening exposing the first port of the body; and a second opening exposing the one or more second ports of the body; and one or more bias members disposed within the housing and configured to bias the body to a central position within the housing assembly; a blind quick-disconnect (QD) fitting attached to the first port of the body; and fluid fittings attached to each of the one or more second ports of the body.

### Example 21

A method comprising: translating a server into a server rack along a first direction effective to couple a fluid coupler assembly of the server with a fitting of the server rack, the coupling causing a body of the fluid coupler assembly to move relative to a housing assembly of the fluid coupler assembly; and translating the server along a second direction that is opposite to the first direction effective to decouple the fluid coupler assembly from the fitting, the decoupling causing the body of the fluid coupler assembly to move from a position corresponding to the coupling to a central position relative to the housing assembly.

### Conclusion

The terminology used herein is for the purpose of describing particular embodiments only and is not intended to be limiting of this disclosure. As used herein, the singular forms “a,” “an,” and “the” are intended to include the plural forms as well, unless the context clearly indicates otherwise. It will be further understood that the terms “includes,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A self-centering floating fluid coupler comprising:
a body including:
a first port; and
one or more second ports in communication with the first port;
a housing assembly surrounding the body, wherein the housing assembly includes:
a first opening exposing the first port of the body; and
a second opening exposing the one or more second ports of the body; and
one or more bias members disposed within the housing assembly and configured to bias the body to a central position within the housing assembly.

2. The self-centering floating fluid coupler of claim 1, wherein the one or more bias members are configured to bias the body towards the first opening of the housing assembly or the second opening of the housing assembly.

3. The self-centering floating fluid coupler of claim 1, wherein:
the housing assembly includes a housing chamfer on an edge of the first opening or an edge of the second opening; and
the body includes a body chamfer on an edge surrounding the first port or an edge surrounding the one or more second ports.

4. The self-centering floating fluid coupler of claim 3, wherein:
the housing chamfer of the housing assembly and the body chamfer of the body are configured to interface with one another; and
the central position corresponds to a position where the body chamfer of the body is centered on the housing chamfer of the housing assembly.

5. The self-centering floating fluid coupler of claim 1, wherein the one or more bias members comprise a plurality of bias members disposed in an array.

6. The self-centering floating fluid coupler of claim 5, wherein the one or more bias members are disposed within respective holes in the body.

7. The self-centering floating fluid coupler of claim 6, wherein the self-centering floating fluid coupler includes a bias member locator configured to locate the one or more bias members relative to the housing assembly.

8. The self-centering floating fluid coupler of claim 1, wherein the housing assembly includes a first portion and a second portion configured to be coupled with one another to surround the body.

9. The self-centering floating fluid coupler of claim 1, wherein at least one of the first port of the body or the one or more second ports of the body are threaded holes.

10. The self-centering floating fluid coupler of claim 1, wherein:
the one or more second ports of the body are two ports; and
the two ports are in communication with the first port of the body.

11. The self-centering floating fluid coupler of claim 10, wherein the two ports of the one or more second ports of the body are different sizes.

12. The self-centering floating fluid coupler of claim 10, wherein the body has an oblong shape about an axis parallel to the first port of the body and the one or more second ports of the body that passes through a centroid of the body.

13. The self-centering floating fluid coupler of claim 10, wherein at least one of the first opening of the housing assembly or the second opening of the housing assembly has an oval shape.

14. The self-centering floating fluid coupler of claim 1, wherein the housing assembly is configured to allow the body to move at least 3 millimeters orthogonally to an axis of the first opening of the housing assembly and an axis of the second opening of the housing assembly.

15. The self-centering floating fluid coupler of claim 1, wherein the housing assembly includes a mounting portion configured to mount the self-centering floating fluid coupler to an external structure.

16. A fluid coupler assembly comprising:
a self-centering floating fluid coupler including:
a body including:
a first port; and
one or more second ports in communication with the first port;
a housing assembly surrounding the body, wherein the housing assembly includes:
a first opening exposing the first port of the body; and
a second opening exposing the one or more second ports of the body; and
one or more bias members disposed within the housing assembly and configured to bias the body to a central position within the housing assembly;
a blind quick-disconnect (QD) fitting attached to the first port of the body; and
fluid fittings attached to each of the one or more second ports of the body.

17. The fluid coupler assembly of claim 16, wherein:
the one or more second ports of the body are two ports; and
the two ports are in communication with the first port of the body.

18. The fluid coupler assembly of claim 16, wherein:
the one or more bias members include a plurality of bias members disposed in an array; and
the plurality of bias members are configured to bias the body towards the first opening of the housing assembly or the second opening of the housing assembly.

19. The fluid coupler assembly of claim 18, wherein:
the body includes an edge surrounding the first port of the body or the one or more second ports of the body; and
the central position corresponds to a position where the edge of the body is centered on the first opening of the housing assembly or the second opening of the housing assembly.

20. A method comprising:
translating a server into a server rack along a first direction effective to couple a fluid coupler assembly of the server with a fitting of the server rack, the coupling causing a body of the fluid coupler assembly to move relative to a housing assembly of the fluid coupler assembly; and
translating the server along a second direction that is opposite to the first direction effective to decouple the fluid coupler assembly from the fitting, the decoupling causing the body of the fluid coupler assembly to move from a position corresponding to the coupling to a central position relative to the housing assembly.
